(19) United States
(12) Patent Application Publication
(10) Pub. No.: US 2013/0181310 A1
(43) Pub. Date: Jul. 18, 2013

(54) SEMICONDUCTOR APPARATUS AND IMAGE SENSOR PACKAGE USING THE SAME

(71) Applicant: Hyun-Su JUN, Seongnam-si (KR)

(72) Inventor: Hyun-Su JUN, Seongnam-si (KR)

(73) Assignee: Samsung Electronics Co., Ltd., Suwon-si (KR)

(21) Appl. No.: 13/598,790

(22) Filed: Aug. 30, 2012

(30) Foreign Application Priority Data
Jan. 12, 2012 (KR) 10-2012-0003916

(51) Int. Cl. H01L 31/0232; H01L 29/06

(52) U.S. Cl. 257/432; 257/622; 257/E31.128; 257/E29.005

(57) ABSTRACT

A semiconductor apparatus and an image sensor package. The image sensor package includes a semiconductor apparatus including a body having a first surface and a second surface which face each other, a first trench formed in the first surface of the body, a second trench formed in the second surface of the body, a third trench formed in a bottom surface of the second trench, and an aperture connecting the first trench to the third trench, a transparent member placed in the third trench and covering the aperture, a mounting board placed under the second surface of the body, and an image sensor chip placed between the mounting board and the transparent member and surrounded by the second trench.

### CROSS-REFERENCE TO RELATED APPLICATIONS

This application claims priority from Korean Patent Application No. 10-2012-0003916 filed on Jan. 12, 2012, in the Korean Intellectual Property Office, the disclosure of which is incorporated herein by reference in its entirety.

### BACKGROUND

1. Field of the Inventive Concept

The present inventive concept relates to a semiconductor apparatus and an image sensor package using the same.

2. Description of the Related Art

As image sensors are applied in more diverse fields, image sensor packages are becoming larger and thinner. The use of various types of parts in the process of assembling an image sensor package can increase the thickness of the image sensor package. In addition, the complexity of the manufacturing process resulting from the assembly of various parts can reduce productivity and affect reliability. Therefore, various researches are being conducted to reduce the thickness of an image sensor package, simplify the manufacturing process, and secure the reliability of the image sensor package.

In an image sensor package, a glass holder is disposed on an image sensor chip, and an optical low pass filter (OLPF) is disposed on the glass holder. The glass holder and the OLPF are adhered to each other. Since the OLPF surrounds an image sensor package holder, the thickness of the image sensor package increases. In addition, since the image sensor package uses multiple holders that are redundant, the manufacturing process is not simplified, and the cost of parts increases.

### SUMMARY

Exemplary embodiments of the inventive concept provide a semiconductor apparatus in which both of a transparent member and an optical filter can be adhered to one holder for an image sensor package through trenches formed in the holder.

Exemplary embodiments of the inventive concept also provide a thin image sensor package which can be assembled in a simple process using the above semiconductor apparatus.

Additional features and utilities of the present general inventive concept will be set forth in part in the description which follows and, in part, will be obvious from the description, or may be learned by practice of the present general inventive concept.

Exemplary embodiments of the present inventive concept provide a semiconductor apparatus comprising, a body having a first surface and a second surface which face each other, a first trench formed in the first surface of the body, a second trench formed in the second surface of the body, a third trench formed in a bottom surface of the second trench, and an aperture connecting the first trench to the third trench.

Exemplary embodiments of the present inventive concept also provide an image sensor package comprising, a semiconductor apparatus comprising a body having a first surface and a second surface which face each other, a first trench formed in the first surface of the body, a second trench formed in the second surface of the body, a third trench formed in a bottom surface of the second trench, and an aperture connecting the first trench to the third trench, a transparent member placed in the third trench and covering the aperture, a mounting board placed under the second surface of the body, and an image sensor chip placed between the mounting board and the transparent member and surrounded by the second trench.

Exemplary embodiments of the present inventive concept also provide a semiconductor apparatus, comprising: a first side including a first trench formed therein; a second side including a second trench formed therein and a third trench formed within the second trench such that the second side includes a stepped portion from the second trench to the third trench; and an aperture connecting the first trench and the third trench.

In an exemplary embodiment, the semiconductor apparatus further includes an optical filter having a first surface adhered within the first trench and a transparent member having a first surface adhered within the third trench such that the aperture is enclosed between the first surfaces of the optical filter and the transparent member.

In an exemplary embodiment, the semiconductor apparatus further includes an image sensor chip connected to a second surface of the transparent member and a mounting board electrically and physically connected to the image sensor chip.

In an exemplary embodiment, a corner at which a bottom surface of the first trench meets the aperture or a corner at which a bottom surface of the third trench meets the aperture is beveled.

In an exemplary embodiment, a corner at which sidewalls of the second trench meet the second side is beveled.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a cross-sectional view of a semiconductor apparatus according to an embodiment of the present inventive concept;

FIG. 2 is a plan view of the semiconductor apparatus shown in FIG. 1;

FIG. 3 is a bottom view of the semiconductor apparatus shown in FIG. 1;

FIG. 4 shows a modified example of the semiconductor apparatus of FIG. 1;

FIG. 5 shows the disposition of a transparent member and an optical filter in the semiconductor apparatus of FIG. 1;

FIG. 6 is a cross-sectional view of a semiconductor apparatus according to another embodiment of the present inventive concept;

FIG. 7 is a view of an image sensor package according to an embodiment of the present inventive concept;

FIGS. 8A and 8B are detailed views of a portion P shown in FIG. 7;

FIG. 9 is a cross-sectional view of an image sensor package according to another embodiment of the present inventive concept;

FIG. 10 is a detailed view of a portion Q shown in FIG. 9;

FIG. 11 is a cross-sectional view of an image sensor package according to another embodiment of the present inventive concept;

FIGS. 12 through 14 are views illustrating processes included in a method of manufacturing an image sensor package according to an embodiment of the present inventive concept; and

FIGS. 15 and 16 are views illustrating processes included in a method of manufacturing an image sensor package according to another embodiment of the present inventive concept.

### DETAILED DESCRIPTION OF THE PREFERRED EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

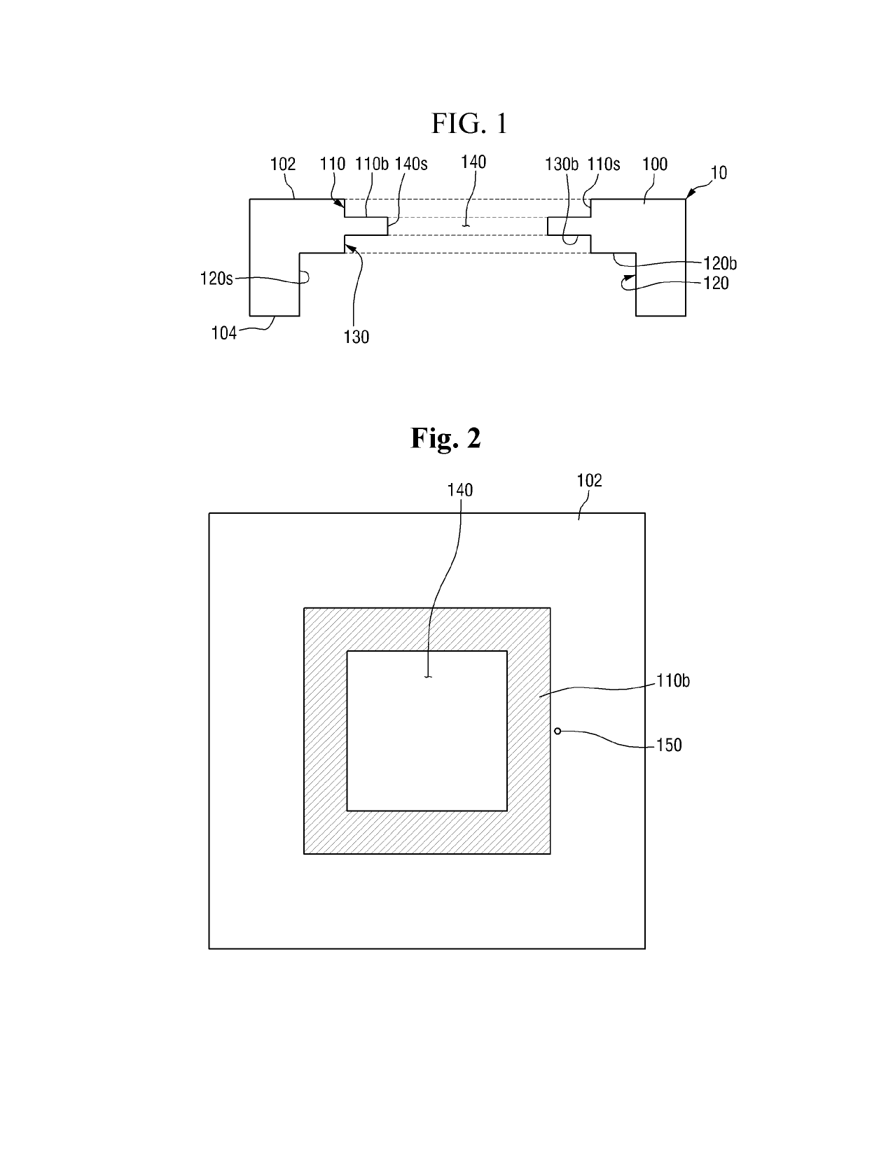

Below, a semiconductor apparatus according to an embodiment of the present inventive concept will be described with reference to FIGS. 1 through 5.

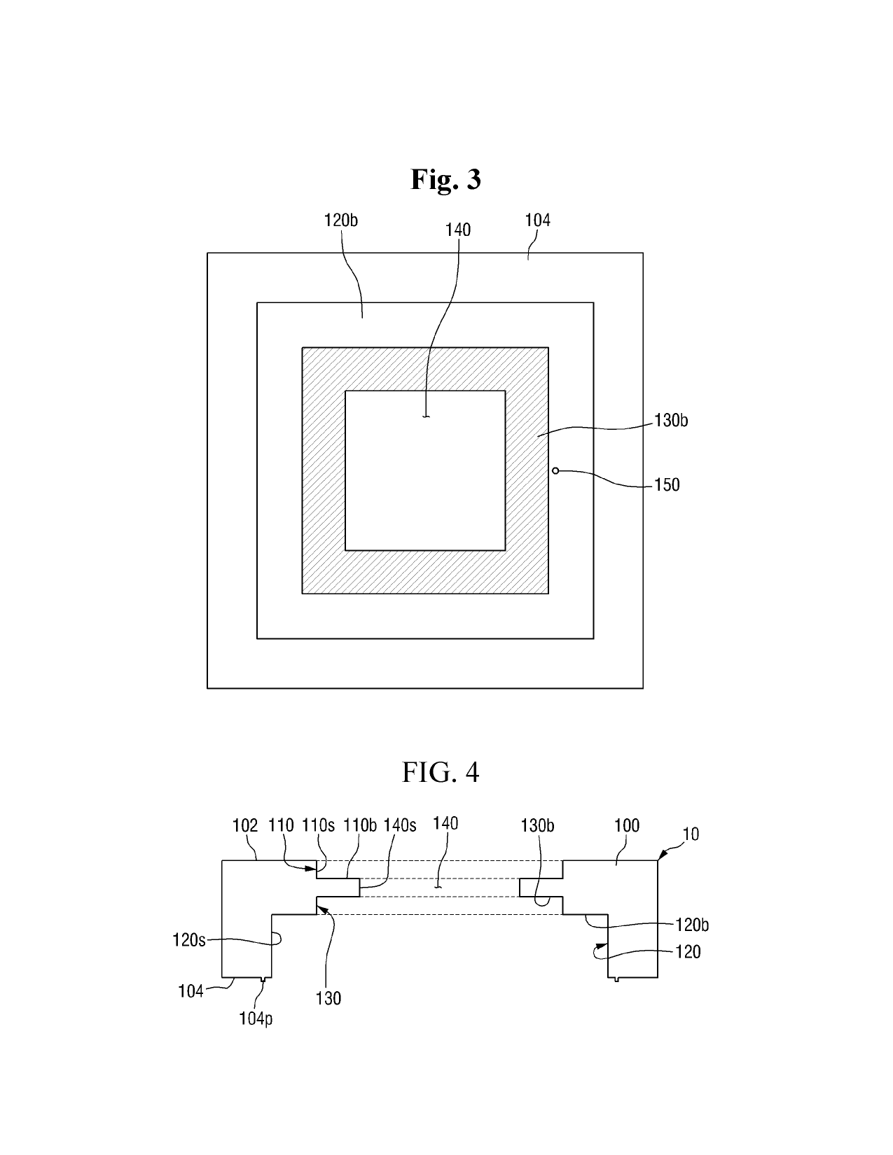

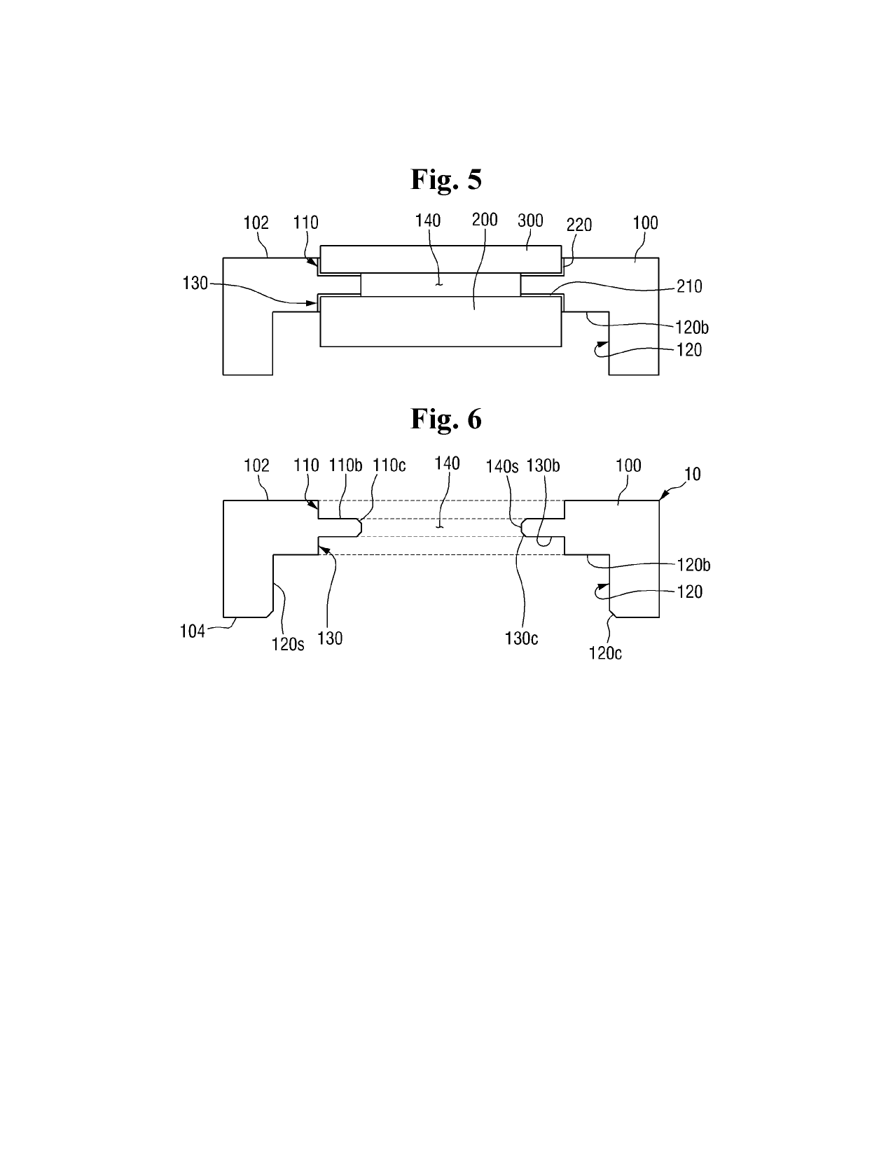

FIG. 1 is a cross-sectional view of a semiconductor apparatus 10 according to an embodiment of the present inventive concept. FIG. 2 is a plan view of the semiconductor apparatus 10 shown in FIG. 1. FIG. 3 is a bottom view of the semiconductor apparatus 10 shown in FIG. 1. FIG. 4 shows a modified example of the semiconductor apparatus 10 of FIG. 1. FIG. 5 shows the disposition of a transparent member 200 and an optical filter 300 in the semiconductor apparatus 10 of FIG. 1.

Referring to FIG. 1, the semiconductor apparatus 10 includes a body 100, a first trench 110, a second trench 120, a third trench 130, and an aperture 140. The body 100 includes a first surface 102 and a second surface 104 which oppose each other. The first trench 110 is formed in the first surface 102 of the body 100, and the second trench 120 is formed in the second surface 104 of the body 100. The third trench 130 is formed in a bottom surface 120b of the second trench 120. The aperture 140 connects the first trench 110 and the third trench 130 formed in the body 100.

Specifically, the first trench 110, the second trench 120, the third trench 130, and the aperture 140 are formed in the body 100. In FIG. 1, the first and second surfaces 102 and 104 of the body 100 and bottom surfaces 110b through 130b of the first through third trenches 110 through 130 included in the semiconductor apparatus 10 according to the current embodiment have substantially the same roughness. For example, no artificial protrusions and recesses may be formed on the first and second surfaces 102 and 104 of the body 100 and the bottom surfaces 110b through 130b of the first through third trenches 110 through 130. However, protrusions and recesses may be formed in an adhesion portion of the semiconductor apparatus 10 which is adhered to, e.g., a mounting board in order to increase adhesion between the semiconductor apparatus 10 and the mounting board. This will be described later with reference to FIGS. 2 and 3.

The body 100 may be made of, for example, polymer or ceramic. Semiconductor apparatuses 10 according to embodiments of the present inventive concept will be described based on the assumption that the body 100 is made of polymer. The body 100 may be formed by, for example, injection molding. The body 100 can be made of any material that can be injection-molded, such as acrylic polymer or amine-based polymer. The first through third trenches 110 through 130 and the aperture 140 can be formed simultaneously in the body 100 using injection molding.

The first trench 110 formed in the first surface 102 of the body 100 is recessed into the body 100 with respect to the first surface 102 of the body 100. The first trench 110 may be formed in the center of the first surface 102 of the body 100. A plane of the first trench 110 may have, but is not limited to, a shape of a square or rectangle. The bottom surface 110b of the first trench 110 may be substantially parallel to the first surface 102 of the body 100. The bottom surface 110b of the first trench 110 is connected to the first surface 102 of the body 100 by sidewalls 110s of the first trench 110. In the drawing, the sidewalls 110s of the first trench 110 are orthogonal to the first surface 102 of the body 100. However, an angle formed by each sidewall 110s of the first trench 110 and the first surface 102 can also be provided as an obtuse angle. Further, the shape of the first trench 110 may vary according to the shape of the optical filter 300 (see FIG. 5) inserted into the first trench 110. That is, the first trench 110 may be processed according to the shape of corners of the optical filter 300 in order to enhance adhesion of the semiconductor apparatus 10 to the optical filter 300.

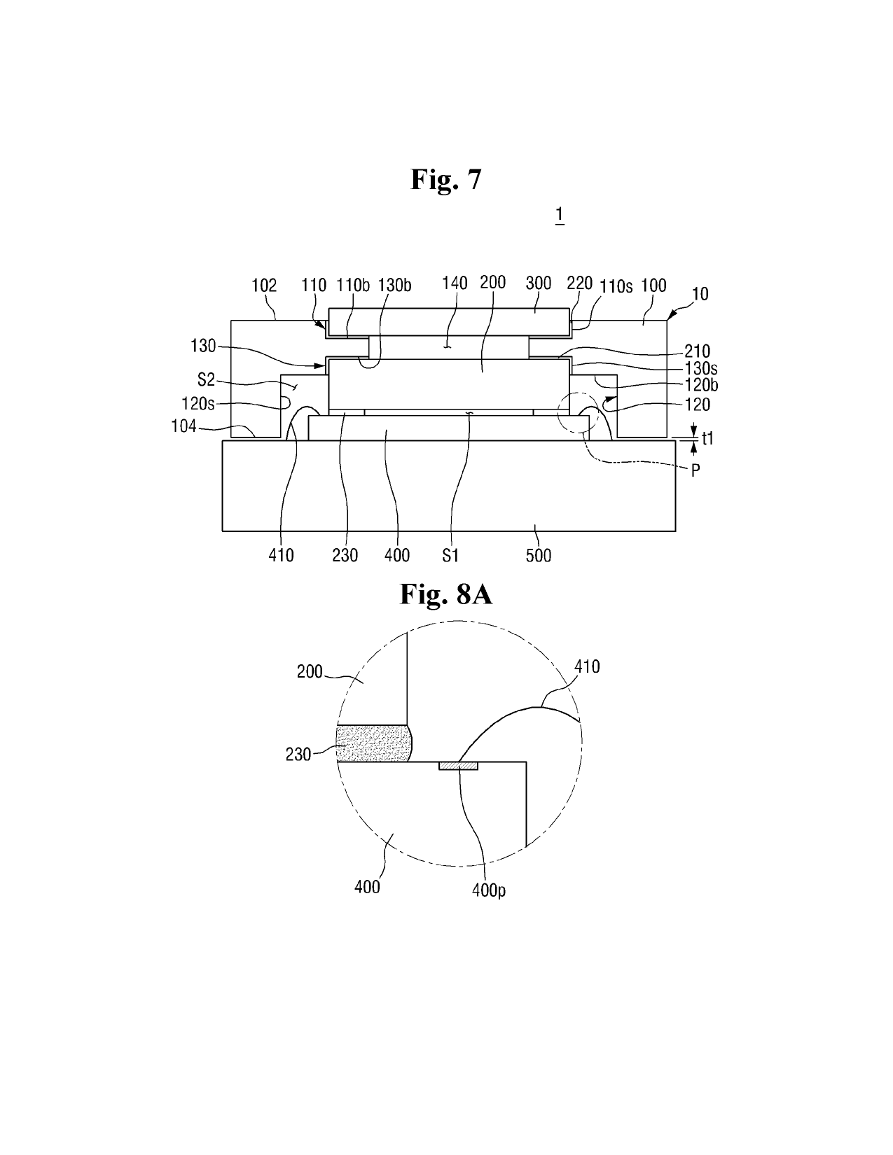

The second trench 120 formed in the second surface 104 of the body 100 is recessed into the body 100 from the second surface 104 of the body 100. The second trench 120 may be formed in the center of the second surface 104 of the body 100. A plane of the second trench 120 may have, but is not limited to, a shape of a square or rectangle. In the drawing, sidewalls 120s of the second trench 120 are orthogonal to the second surface 104 of the body 100. However, an angle formed by each sidewall of the second trench 120 and the second surface 104 of the body 100 can also be provided as an obtuse angle. The slope of the sidewalls of the second trench 120 may vary according to the shape of an image sensor chip 400 (see FIG. 7) and the shape of wirings 410 (see FIG. 7) that connect the image sensor chip 400 to a mounting board 500 (see FIG. 7).

The third trench 130 formed in the bottom surface 120b of the second trench 120 is recessed toward the first trench 110 from the bottom surface 120b of the second trench 120. The third trench 130 may be formed in the center of the bottom surface 120b of the second trench 120. A plane of the third trench 130 may have, but is not limited to, a shape of a square or rectangle. The bottom surface 130b of the third trench 130 may be substantially parallel to the bottom surface 110b of the first trench 110. In the drawing, sidewalls of the third trench 130 are orthogonal to the bottom surface 110b of the first trench 110. However, an angle formed by each sidewall of the third trench 130 and the first surface 102 of the body 100 can also be provided as an obtuse angle. Further, the shape of the third trench 130 may vary according to the shape of the transparent member 200 (see FIG. 5) inserted into the third trench 130. That is, the third trench 130 may be processed according to the shape of corners of the transparent member 200 in order to enhance adhesion of the semiconductor apparatus 10 to the transparent member 200.

The aperture 140 connects the first trench 110 to the third trench 130. That is, the bottom surface 110b of the first trench 110 is connected to the bottom surface 120b of the second trench 120 by sidewalls 140s of the aperture 140. The aperture 140 may have, but is not limited to, a shape of a square or rectangle.

Referring to FIG. 2, the square shape aperture 140 illustrated is surrounded by the bottom surface 110b of the first trench 110. The bottom surface 110b of the first trench 110 is surrounded by the first surface 102 of the body 100 which has a step difference from the bottom surface 110b of the first trench 110. An air vent hole 150 may be formed in the first surface 102 of the body 100. Since gas inside an image sensor package is released to the outside through the air vent hole 150, the image sensor package can be prevented from being destroyed due to pressure. The air vent hole 150 is optional, depending on the structure of the image sensor package. This will be described later with reference to FIGS. 7 and 9.

Referring to FIG. 3, the bottom surface 130b of the third trench 130 surrounds the aperture 140. In addition, the bottom surface 120b of the second trench 120 and the second surface 104 of the body 100, which have a step difference from the bottom surface 130b of the third trench 130, sequentially surround the bottom surface 130b of the third trench 130. An air vent hole 150 may be formed in the bottom surface 120b of the second trench 120. The air vent hole 150 formed in the image sensor package may connect the first surface 102 of the body 100 to the second surface 104 of the body 100.

Referring to FIGS. 2 and 3, the bottom surface 110b of the first trench 110 and the bottom surface 130b of the third trench 130 are hatched. This indicates that the bottom surface 110b of the first trench 110 and the bottom surface 130b of the third trench 130 may include protrusions and recesses. In other words, a first roughness of the first surface 102 of the body 100 may be different from a second roughness of the bottom surface 110b of the first trench 110. In addition, a third roughness of the bottom surface 120b of the second trench 120 may be different from a fourth roughness of the bottom surface 130b of the third trench 130. The difference in roughness between the above surfaces can be reduced by forming artificial protrusions and recesses on the bottom surface 110b of the first trench 110 and the bottom surface 130b of the third trench 130.

To describe the semiconductor apparatus 10 according to the present embodiment, a case where protrusions and recesses are formed on the bottom surface 110b of the first trench 110 and the bottom surface 130b of the third trench 130 has been used as an example. Therefore, one or more of the bottom surface 110b of the first trench 110 and the bottom surface 130b of the third trench 130 may include protrusions and recesses. The protrusions and recesses included in the bottom surface 110b of the first trench 110 and the bottom surface 130b of the third trench 130 may be a regular repetition of, for example, a mesh shape, a saw-toothed shape, or a wave shape. The protrusions and recesses may be formed using a physical method or a chemical method. In the chemical method, an adhesion surface of a semiconductor apparatus may be etched or corroded using chemicals. Examples of the physical method may include sand blasting and injection molding in which protruding and recessed shapes are formed in a mold to form protrusions and recesses. However, the method of forming protrusions and recesses is not limited to the above methods.

A modified example of the semiconductor apparatus 10 shown in FIG. 1 will now be described with reference to FIG. 4.

Referring to FIG. 4, a semiconductor apparatus 10 may further include one or more protrusions 104p which protrude from the second surface 104 of the body 100. The protrusions 104p may be formed respectively on four sides of the second surface 104 of the body 100 around the second trench 120. However, the present inventive concept is not limited thereto, and the protrusions 104p can also be formed at arbitrary locations on the second surface 104 of the body 100. The protrusions 104p may be formed to align the semiconductor apparatus 10 with the mounting board 500 (see FIG. 7). In addition, the protrusions 104p may be formed to increase adhesion between the semiconductor apparatus 10 and the mounting board 500. When a semiconductor apparatus of an image sensor package includes the protrusions 104p, the mounting board 500 may include recesses at locations corresponding respectively to the protrusions 104p.

Referring to FIG. 5, the semiconductor apparatus 10 may further include the transparent member 200 or the optical filter 300. The transparent member 200 may be placed within the third trench 130 and cover the aperture 140. The transparent member 200 may be, e.g., a glass plate. The transparent member 200 may be adhered to the semiconductor apparatus 10 by a first adhesive film 210. The transparent member 200 is adhered to the bottom surface 130b of the third trench 130 and the sidewalls of the third trench 130 by the first adhesive film 210. Part of sidewalls of the transparent member 200 may not overlap the sidewalls of the third trench 130. That is, the transparent member 200 may be raised higher than the bottom surface 120b of the second trench 120. However, this is merely an example used to describe the semiconductor apparatus 10 according to exemplary embodiments of the present inventive concept, and the present inventive concept is not limited to this example.

The optical filter 300 is placed within the first trench 110 and covers the aperture 140 with respect to the first surface 102 side of the body 100. The optical filter 300 and the transparent member 200 face each other with the aperture 140 interposed therebetween. The optical filter 300 may be, for example, an optical low frequency filter (OLPF). The optical filter 300 can remove moire fringes to realize a high-quality image sensor system. The optical filter 300 is adhered to the bottom surface 110b of the first trench 110 and the sidewalls of the first trench 110 by a second adhesive film 220. The optical filter 300 may be raised higher than the first surface 102 of the body 100. However, the present inventive concept is not limited thereto.

A semiconductor apparatus according to another embodiment of the present inventive concept will now be described with reference to FIG. 6. The semiconductor apparatus according to the current embodiment is substantially the same as the semiconductor apparatus 10 described above with reference to FIGS. 1 through 5, except that an adhesion portion of the semiconductor apparatus is beveled, and thus a redundant description thereof will be omitted or made briefly.

FIG. 6 is a cross-sectional view of a semiconductor apparatus 10 according to another embodiment of the present inventive concept.

Referring to FIG. 6, a corner at which a bottom surface 110b of a first trench 110 meets each sidewall 140s of an aperture 140 is beveled to form a first beveled surface 110c. A corner at which a second surface 104 of a body 100 meets each sidewall 120s of a second trench 120 is beveled to form a second beveled surface 120c. A corner at which a bottom surface 130b of a third trench 130 meets each sidewall 140s of the aperture 140 is beveled to form a third beveled surface 130c. To describe the semiconductor apparatus 10 according to the present embodiment, the first through third beveled surfaces 110c, 120c and 130c are illustrated in the drawing. That is, the semiconductor apparatus 10 may include one or more of the first through third beveled surfaces 110c, 120c and 130c. The first through third beveled surfaces 110c, 120c and 130c shown in the drawing are flat surfaces. However, they can also be curved surfaces having a curvature. The formation of such beveled surfaces can increase the adhesion of the semiconductor apparatus 10 to a mounting board 500 (see FIG. 7), a transparent member 200 (see FIG. 7) and an optical filter 300 (see FIG. 7), thereby improving the reliability of an image sensor package.

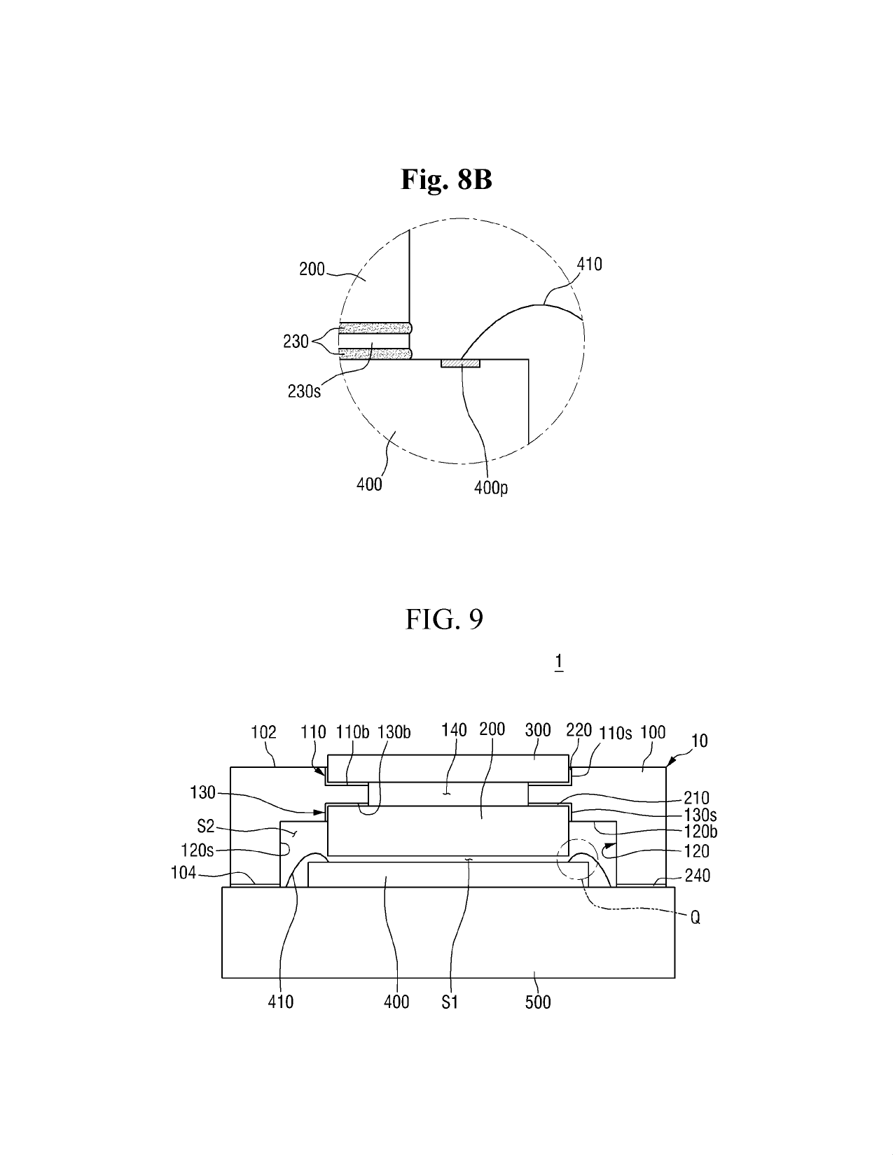

An image sensor package according to an embodiment of the present inventive concept will now be described with reference to FIGS. 7 through 8B. A semiconductor apparatus used in the image sensor package is substantially the same as any one of the semiconductor apparatuses 10 described above, and thus a redundant description thereof will be omitted or provided briefly.

FIG. 7 is a view of an image sensor package 1 according to an embodiment of the present inventive concept. FIGS. 8A and 8B are detailed views of a portion P shown in FIG. 7.

Referring to FIG. 7, the image sensor package 1 includes a semiconductor apparatus 10, a transparent member 200, an image sensor chip 400, and a mounting board 500. The image sensor package 1 may further include an optical filter 300. The image sensor chip 400 may further include wirings 410 which electrically connect the image sensor chip 400 to the mounting board 500. The image sensor package 1 may further include first through third adhesive films 210, 220 and 230. The transparent member 200 is placed in a third trench 130 formed in a body 100 and covers an aperture 140. The optical filter 300 is placed in a first trench 110 formed in the body 100 and covers another side of the aperture 140 with respect to the second surface 104 side of the body 100. The transparent member 200 and the optical filter 300 face each other with the aperture 140 positioned therebetween. The mounting board 500 is placed under the semiconductor apparatus 10, specifically, under a second surface 104 of the body 100. The image sensor chip 400 is disposed between the mounting board 500 and the transparent member 200 and surrounded by the semiconductor apparatus 10. That is, the image sensor chip 400 is surrounded by a second trench 120 and placed within the second trench 120.

Referring to FIG. 7, the semiconductor apparatus 10 includes the body 100, the first through third trenches 110, 120 and 130, and the aperture 140. The body 100 includes a first surface 102 and the second surface 104 which oppose each other. The first trench 110 is formed in the first surface 102 of the body 100, the second trench 120 is formed in the second surface 104 of the body 100, and the third trench 130 is formed in a bottom surface 120b of the second trench 120. The aperture 140 connects the first trench 110 and the third trench 130 formed in the body 100. Protrusions and recesses described above with reference to FIGS. 2 and 3 may be formed in a bottom surface 130b of the third trench 130 which is adhered to the transparent member 200 or a bottom surface 110b of the first trench 110 which is adhered to the optical filter 300. When both of the bottom surface 110b of the first trench 110 and the bottom surface 130b of the third trench 130 include protrusions and recesses, the shape and/or roughness of the protrusions and recesses formed in the bottom surface 110b of the first trench 110 may be the same as the shape and/or roughness of the bottom surface 130b of the third trench 130. Here, the term ‘same’ encompasses not only a case where two surfaces are completely the same in their shape and/or roughness but also a case where fine differences exist between the two surfaces due to processing margins.

Referring to FIG. 7, the transparent member 200 placed in the third trench 130 is connected to the third trench 130 by the first adhesive film 210. The transparent member 200 is adhered to the bottom surface 130b of the third trench 130 and sidewalls 130s of the third trench 130 by the first adhesive film 210. A distance from the bottom surface 130b of the third trench 130 to a surface of the transparent member 200 which faces the image sensor chip 400 may be greater than a height of the sidewalls 130s of the third trench 130. Therefore, a part of a side surface of the transparent member 200 may face the sidewalls 130s of the third trench 130, and the other part of the side surface of the transparent member 200 may face sidewalls 120s of the second trench 120. A thickness of the transparent member 200 may be determined in view of a height of the wirings 410. The transparent member 200 should be thick enough to fully protect the wirings 410. Although not shown in FIG. 7, part of the first adhesive film 210 may be placed on the bottom surface 120b of the second trench 120. The first adhesive film 210 may be placed in a band shape on the bottom surface 120b of the second trench 120 which adjoins the third trench 130.

The transparent member 200 is connected to the image sensor chip 400 in addition to the semiconductor apparatus 10. The transparent member 200 is connected to the image sensor chip 400 by the third adhesive film 230. The transparent member 200 is adhered to a top surface of the image sensor chip 400 by the third adhesive film 230. The third adhesive film 230 is placed around a light-receiving portion (not shown) of the image sensor chip 400. The third adhesive film 230 adheres edges of the transparent member 200 to a region around the light-receiving portion of the image sensor chip 400. As the transparent member 200 and the image sensor chip 400 are adhered to each other, a first space S1 surrounded by the transparent member 200, the image sensor chip 400 and the third adhesive film 230 is sealed. The sealed first space S1 prevents particles from entering the light-receiving portion of the image sensor chip 400, thereby reducing the feeling of a presence of foreign matter in a sensed image.

Referring to FIG. 7, the image sensor chip 400 is placed between the mounting board 500 and the transparent member 200. A bottom surface of the image sensor chip 400 is adhered, and thus connected, to the mounting board 500 by an adhesive film (not shown), and a top surface of the image sensor chip 400 is connected to the transparent member 200 by the third adhesive film 230. It is to be noted that the terms bottom surface and top surface are relative terms only, and the surfaces of the image sensor chip 400 may be referred to in the opposite manner. Thus, a description of top and bottom surfaces is for ease of description and understanding of the drawings only. The image sensor chip 400 may be electrically connected to the mounting board 500 by the wirings 410. The wirings 410 are formed on a surface of the image sensor chip 400 which faces the transparent member 200. The wirings 410 may be formed using a conventional wiring method or a reverse wiring method. The wirings 410 may not overlap the transparent member 200 and the third adhesive film 230. That is, the wirings 410 may be placed around the third adhesive film 230 and connected to the image sensor chip 400. The wirings 410 may be positioned in a second space S2 that can be formed by the second trench 120, the transparent member 200, the third adhesive film 230, and the image sensor chip 400. In other words, the second space S2 may surround the wirings 410. The mounting board 500 may be, but is not limited to, a printed circuit board (PCB).

In the image sensor package 1 according to the present embodiment, the body 100, the transparent member 200, the image sensor chip 400 and the mounting board 500 are sequentially connected to each other by adhesive films to form one fixed body. Although the mounting board 500 is placed under the second surface 104 of the body 100, it does not necessarily contact the second surface 104 of the body 100. In the image sensor package 1 according to the current embodiment of the present inventive concept, an adhesive film which adheres the mounting board 500 to the second surface 104 of the body 100 may not be used. Depending on a process of manufacturing the image sensor package 1, the mounting board 500 and the second surface 104 of the body 100 may contact each other. Alternatively, depending on the tolerance of the process of manufacturing the image sensor package 1, an air gap t1 may be formed between the mounting board 500 and the second surface 104 of the body 100. In FIG. 7, the air gap t1 is formed between the second surface 104 of the body 100 and the mounting board 500.

Referring to FIG. 7, the second space S2 is a space surrounded by the second trench 120, the transparent member 200, the third adhesive film 230, the image sensor chip 400 and the air gap t1. The second space S2 may not be sealed off from the outside of the image sensor package 1. That is, part of each of the wirings 410 in the second space S2 may be surrounded by the air gap t1. Since air inside the second space S2 can flow out of the image sensor package 1 through the air gap t1, an air vent hole 150 may not be formed on the first surface 102 of the body 100, unlike in FIG. 2. The air vent hole 150 prevents the pressure inside the second space S2 from increasing during a manufacturing process, and thus destroying the image sensor package 1. However, since the second space S2 is not sealed due to the non-adhesion of the second surface 104 of the body 100 to the mounting board 500, the pressure of the second space S2 can be controlled without using the air vent hole 150.

Referring to FIG. 7, the optical filter 300 placed within the first trench 110 is connected to the first trench 110 by the second adhesive film 220. The optical filter 300 is adhered to the bottom surface 110b of the first trench 110 and sidewalls 110s of the first trench 110 by the second adhesive film 220. A top surface of the optical filter 300 may be, but is not limited to, higher than the first surface 102 of the body 100. Although not shown in FIG. 7, part of the second adhesive film 220 may be placed on the first surface 102 of the body 100. The second adhesive film 220 may be placed in a band shape on the first surface 102 of the body 100 which adjoins the first trench 110. The first through third adhesive films 210, 220 and 230 may be, for example, epoxy.

Referring to FIG. 8A, only the third adhesive film 230 is placed between the transparent member 200 and the image sensor chip 400. Each of the wirings 410 is connected to a connection pad 400p formed on the image sensor chip 400. The connection pad 400p is formed on each portion of the image sensor chip 400 which is not overlapped by the third adhesive film 230. Therefore, each wiring 410 connected to the connection pad 400p does not contact the third adhesive film 230 and the transparent member 200 formed on the third adhesive film 230. The wirings 410 are not overlapped by the transparent member 200 and the third adhesive film 230 when seen in a plane view. Although the third adhesive film 230 has a curved side surface in the drawing, the present embodiment is not limited thereto. In addition, part of the third adhesive film 230 may protrude further than the side surface of the transparent member 200. However, the third adhesive film 230 may also be recessed from the side surface of the transparent member 200 in a direction away from the connection pad 400p. There is no correlation between a height of a topmost part of each wiring 410 and a thickness of the third adhesive film 230.

Referring to FIG. 8B, a spacer 230s may further be provided between the transparent member 200 and the image sensor chip 400. The spacer 230s may be adhered and connected to the transparent member 200 and the image sensor chip 400 by the third adhesive film 230 formed on both sides of the spacer 230s. The spacer 230s may secure the first space S1 (see FIG. 7) between the transparent member 200 and the image sensor chip 400, or may be used to improve the durability of the image sensor package 1. A shape of the spacer 230s may be the same as a planar shape of the transparent member 200. However, the present embodiment is not limited thereto. The spacer 230s includes a through hole (not shown) in the center thereof to allow incident light to reach the light receiving portion of the image sensor chip 400 without being blocked. That is, the spacer 230s may be an object that includes inner and outer sidewalls and an aperture formed in the center thereof.

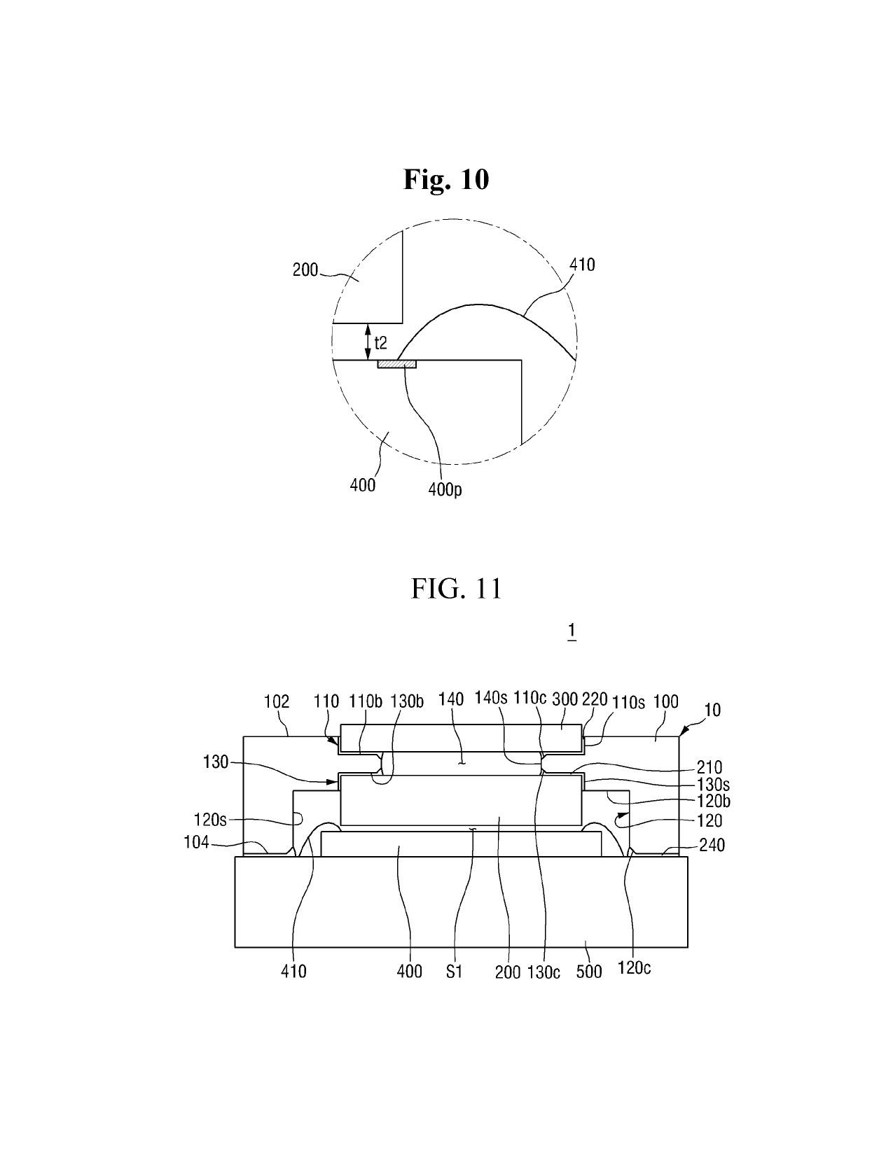

An image sensor package according to another embodiment of the present inventive concept will now be described with reference to FIGS. 9 and 10. The image sensor package according to the current embodiment is substantially the same as the image sensor package 1 described above with reference to FIG. 7, except that a transparent member 200 is not adhered to an image sensor chip 400 and that a second surface 104 of a body 100 is adhered to a mounting board 500, and thus a redundant description thereof will be omitted or made briefly.

FIG. 9 is a cross-sectional view of an image sensor package 1 according to another embodiment of the present inventive concept. FIG. 10 is a detailed view of a portion Q shown in FIG. 9.

Referring to FIG. 9, a first adhesive film 210 adheres and connects a transparent member 200 to a third trench 130. A fourth adhesive film 240 adheres and connects a second surface 104 of a body 100 to a mounting board 500. Unlike in FIG. 7, in FIG. 9, the transparent member 200 and an image sensor chip 400 are not connected to each other, but face each other. A first space S1 between the transparent member 200 and the image sensor chip 400 is not a sealed space. A second space S2 surrounded by a second trench 120, the fourth adhesive film 240, the image sensor chip 400 and the transparent member 200 is connected to the first space S1. The inside of the image sensor package 1 which is formed by the first space S1 and the second space S2 is sealed off from the outside of the image sensor package 1. The fourth adhesive film 240 may be, for example, epoxy.

In the image sensor package 1 according to exemplary embodiments of the present inventive concept, the transparent member 200, the body 100, the mounting board 500, and the image sensor chip 400 may be connected sequentially to each other by adhesive films to form one fixed body. Since the inside of the image sensor package 1 is sealed off from the outside, an air vent hole 150 (see FIG. 2) may be formed to release the air inside the image sensor package 1 to the outside.

Referring to FIG. 10, a wiring 410 which electrically connects the image sensor chip 400 to the mounting board 500 is connected to a connection pad 400p. In the drawing, part of the connection pad 400p is disposed under the transparent member 200 to be overlapped by the transparent member 200. However, the present inventive concept is not limited thereto. That is, the wiring 410 may not overlap the first space S1 (see FIG. 9). In the image sensor package 1 according to exemplary embodiments of the present inventive concept, if the connection pad 400p is placed on a portion of the image sensor chip 400 which is overlapped by the first space S1 (see FIG. 9), the wiring 410 may be overlapped by the transparent member 200. That is, part of the wiring 410 may be positioned within the first space S1 (see FIG. 9). A height t2 of the first space S1 may be determined in view of a height of a topmost part of the wiring 410. When the topmost part of the wiring 410 is positioned within the first space S1, the height t2 of the first space S1 should be great enough to prevent the transparent member 200 and the wiring 410 from contacting each other.

An image sensor package according to another embodiment of the present inventive concept will now be described with reference to FIG. 11. The image sensor package according to the current embodiment is substantially the same as the image sensor package 1 described above with reference to FIG. 9, except that an adhesion portion of a semiconductor apparatus 10 is beveled, and thus a redundant description thereof will be omitted or made briefly.

FIG. 11 is a cross-sectional view of an image sensor package 1 according to another embodiment of the present inventive concept.

Referring to FIG. 11, a corner at which a bottom surface 110b of a first trench 110 meets an aperture 140 is beveled. A corner at which each sidewall 120s of a second trench 120 meets a second surface 104 of a body 100 is beveled. A corner at which a bottom surface 130b of a third trench 130 meets the aperture 140 is beveled. A first beveled surface 110c is positioned between the bottom surface 110b of the first trench 110 and each sidewall 140s of the aperture 140. A second beveled surface 120c is positioned between each sidewall 120s of the second trench 120 and the second surface 104 of the body 100. A third beveled surface 130c is positioned between the bottom surface 130b of the third trench 130 and each sidewall 140s of the aperture 140. A first adhesive film 210 contacts the sidewalls 130s of the third trench 130, the bottom surface 130b of the third trench 130, the third beveled surface 130c, and the transparent member 200. A second adhesive film 220 contacts the bottom surface 110b of the first trench 110, the sidewalls 110s of the first trench 110, the first beveled surface 110c, and an optical filter 300. A fourth adhesive film 240 contacts the second surface 104 of the body 100, a mounting board 500, and the second beveled surface 120c. Since the above configuration is merely an example used to describe the image sensor package 1 according to an embodiment of the present inventive concept, one or more of the first through third beveled surfaces 110c through 130c can be formed. The first through third beveled surfaces 110c through 130c respectively increase the adhesion areas of the second adhesive film 220, the fourth adhesive film 240 and the first adhesive film 210, thereby increasing the adhesion of an adhesion portion of the image sensor package 1.

A method of manufacturing an image sensor package according to an embodiment of the present inventive concept will now be described with reference to FIGS. 7 and 12 through 14.

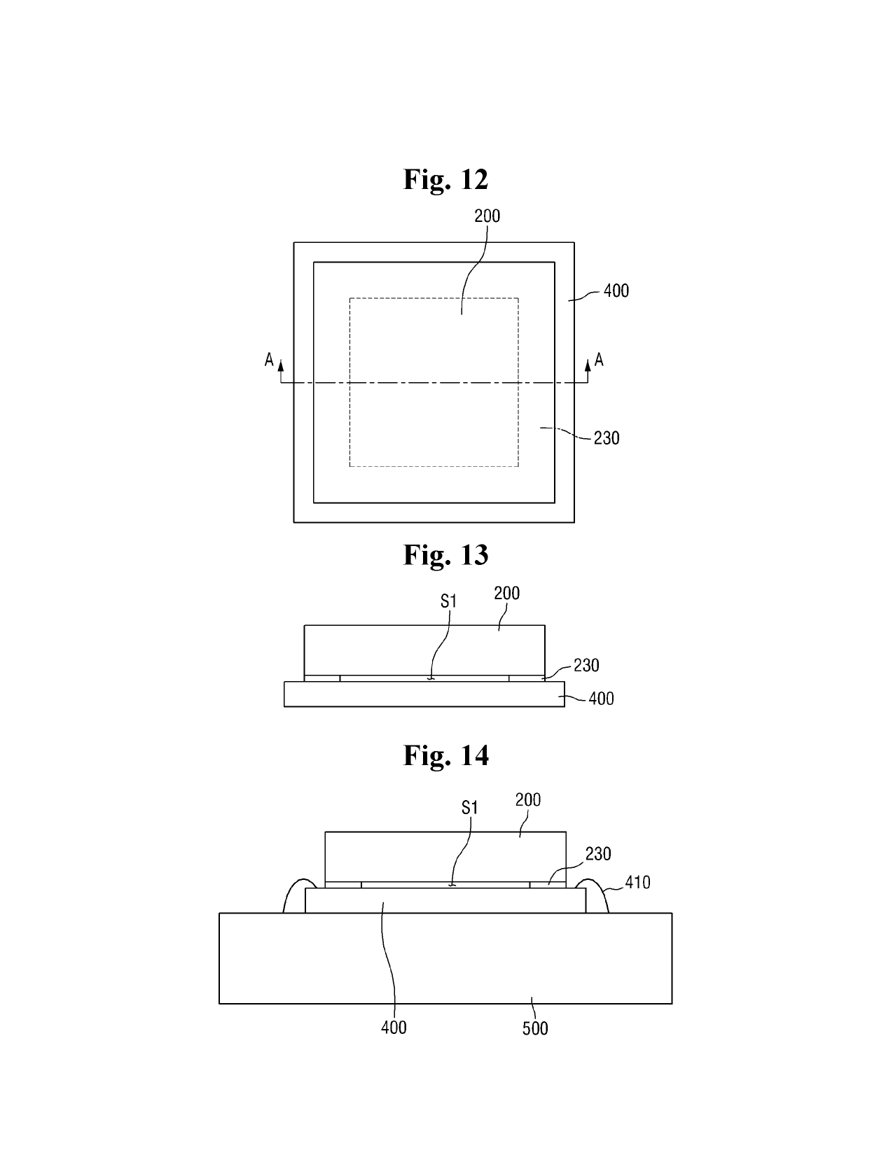

FIGS. 12 through 14 are views illustrating a process of manufacturing the image sensor package 1 of FIG. 7.

Referring to FIGS. 12 and 13, a wafer having an image sensor device is made thin by a polishing process. Then, the thin wafer is expanded by cutting the wafer into sizes of an image sensor chip. An image sensor chip 400 is examined to determine whether it is non-defective. When the image sensor chip 400 is determined to be a non-defective chip, a transparent member 200 is adhered onto the image sensor chip 400 using a third adhesive film 230. Then, the image sensor chip 400 where the transparent member 200 is adhered is separated from the wafer. FIG. 12 illustrates the separated image sensor chip 400, and FIG. 13 is a cross section taken along the line A-A of FIG. 12. The transparent member 200 is positioned in the center of the image sensor chip 400, and the third adhesive film 230 is positioned under the transparent member 200. The third adhesive film 230 is formed in a band shape along edges of the transparent member 200. The inside of the third adhesive film 230 may be a light receiving portion of the image sensor chip 400. A first space S1 formed by the transparent member 200, the image sensor chip 400 and the third adhesive film 230 may be sealed.

Referring to FIG. 14, the image sensor chip 400 coupled to the transparent member 200 is placed on a mounting board 500. The image sensor chip 400 may be adhered to the mounting board 500 using an adhesive film (not shown). Here, a curing process may be performed so that the image sensor chip 400 can stably adhere to the mounting board 500. Subsequently, the mounting board 500 and the image sensor chip 400 are electrically connected to each other using wirings 410.

Referring to FIG. 7, the third trench 130 and the transparent member 200 included in the semiconductor apparatus 10 of FIG. 1 are adhered to each other using a first adhesive film 210. Here, a curing process may be performed so that the semiconductor apparatus 10 can stably adhere to the transparent member 200. An optical filter 300 is connected to the semiconductor apparatus 10 using a second adhesive film 220, thereby completing an image sensor package. The semiconductor apparatus 10 and the optical filter 300 can also be adhered to each other using the second adhesive film 220 before the semiconductor apparatus 10 and the transparent member 200 are adhered to each other.

A method of manufacturing an image sensor package according to another embodiment of the present inventive concept will now be described with reference to FIGS. 9, 15 and 16.

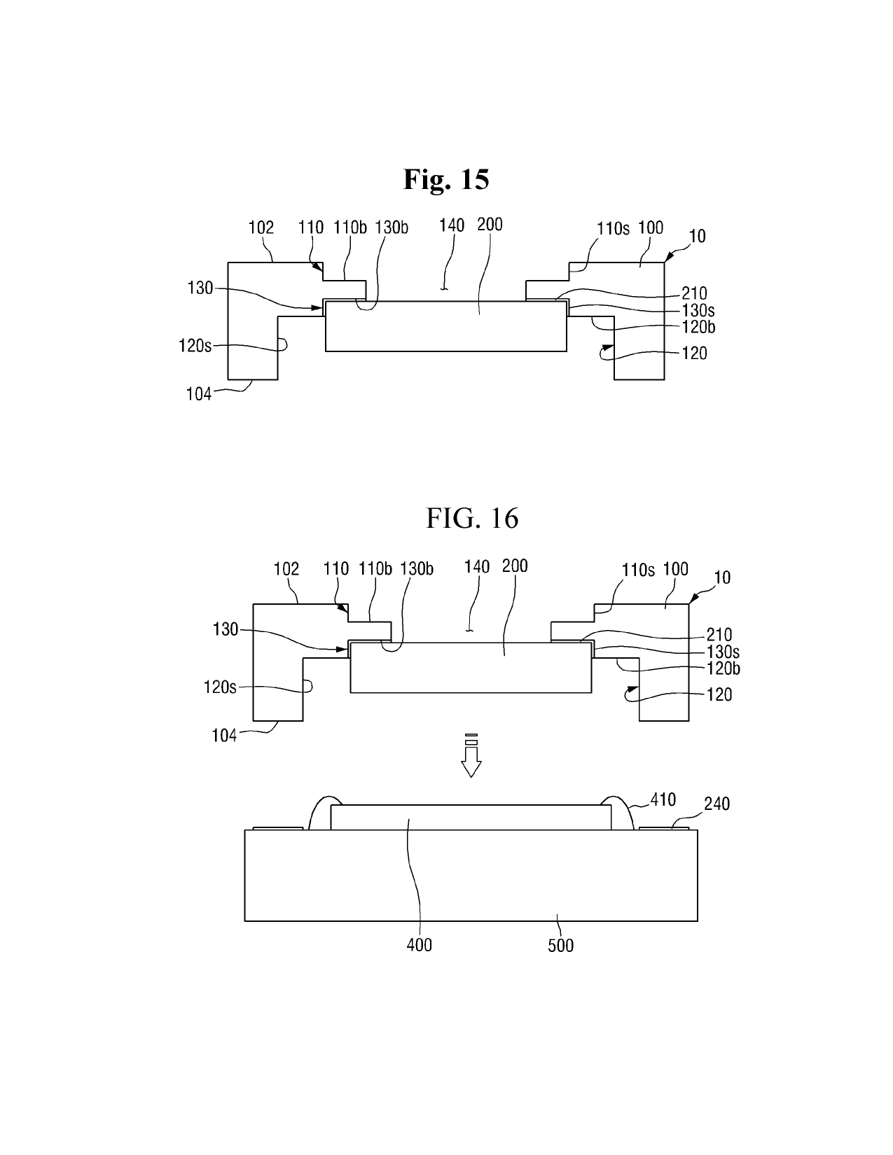

FIGS. 15 and 16 are views illustrating a process of manufacturing the image sensor package 1 of FIG. 9.

Referring to FIG. 15, the third trench 130 and the transparent member 200 included in the semiconductor apparatus 10 of FIG. 1 are connected to each other using a first adhesive film 210. An optical filter may further be connected to the semiconductor apparatus 10 which includes the transparent member 200. However, the present inventive concept is not limited thereto. In the method of manufacturing an image sensor package according to the present inventive concept, the semiconductor apparatus 10 is adhered to a mounting board 500 before the optical filter is connected to the semiconductor apparatus 10.

Referring to FIG. 16, an image sensor chip 400 is placed on the mounting board 500. The image sensor chip 400 may be adhered to the mounting board 500 using an adhesive film (not shown). Here, a curing process may be performed so that the image sensor chip 400 can stably adhere to the mounting board 500. Subsequently, the mounting board 500 and the image sensor chip 400 may be electrically connected to each other using wirings 410. A fourth adhesive film 240 is formed at a location on the mounting board 500 which corresponds to a second surface 104 (see FIG. 15) of a body 100. However, the fourth adhesive film 240 can also be formed on the second surface 104 of the body 100, instead of on the mounting board 500. After the mounting board 500 and the image sensor chip 400 are connected to each other using the wirings 410, the semiconductor apparatus 10 manufactured in FIG. 15 is adhered to the mounting board 500. Then, an optical filter 300 is connected to the semiconductor apparatus 10 using a second adhesive film 220, thereby completing an image sensor package.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A semiconductor apparatus comprising:
a body having a first surface and a second surface which oppose each other;
a first trench formed in the first surface of the body;
a second trench formed in the second surface of the body;
a third trench formed in a bottom surface of the second trench; and
an aperture connecting the first trench to the third trench.

2. The semiconductor apparatus of claim 1, further comprising:
a transparent member placed in the third trench and covering the aperture.

3. The semiconductor apparatus of claim 1, further comprising:
an optical filter placed in the first trench and covering the aperture.

4. The semiconductor apparatus of claim 1, wherein a corner at which a bottom surface of the first trench meets the aperture or a corner at which a bottom surface of the third trench meets the aperture is beveled.

5. An image sensor package comprising:
a semiconductor apparatus comprising a body having a first surface and a second surface which oppose each other, a first trench formed in the first surface of the body, a second trench formed in the second surface of the body, a third trench formed in a bottom surface of the second trench, and an aperture connecting the first trench to the third trench;
a transparent member placed in the third trench and covering the aperture;
a mounting board placed under the second surface of the body; and
an image sensor chip placed between the mounting board and the transparent member and surrounded by the second trench.

6. The image sensor package of claim 5, further comprising:
an optical filter placed in the first trench and covering the aperture.

7. The image sensor package of claim 5, wherein a corner at which a bottom surface of the first trench meets the aperture or a corner at which a bottom surface of the third trench meets the aperture is beveled.

8. The image sensor package of claim 5, further comprising:
protrusions and recesses formed in the bottom surface of the third trench.

9. The image sensor package of claim 5, further comprising:
a first adhesive film which connects the transparent member to the third trench and a second adhesive film which connects the transparent member to the image sensor chip.

10. The image sensor package of claim 9, wherein a space formed by the transparent member, the image sensor chip and the second adhesive film is sealed.

11. The image sensor package of claim 9, wherein an air gap is formed between the second surface of the body and the mounting board.

12. The image sensor package of claim 9, further comprising:
a spacer between the transparent member and the image sensor chip, wherein the spacer is connected to the image sensor chip and the transparent member by the second adhesive film.

13. The image sensor package of claim 9, further comprising:
wirings which electrically connect the image sensor chip to the mounting board, wherein the wirings are placed around the adhesive film and connected to the image sensor chip, and a space formed by the second trench, the transparent member, the second adhesive film and the image sensor chip surrounds the wirings.

14. The image sensor package of claim 5, further comprising:
a first adhesive film which connects the transparent member to the third trench and a second adhesive film which connects the second surface of the body to the mounting board.

15. The image sensor package of claim 14, further comprising:
wirings which electrically connect the image sensor chip to the mounting board, wherein the wirings are overlapped by the transparent member.

16. A semiconductor apparatus, comprising:
a first side including a first trench formed therein;
a second side including a second trench formed therein and a third trench formed within the second trench such that the second side includes a stepped portion from the second trench to the third trench; and
an aperture connecting the first trench and the third trench.

17. The semiconductor apparatus of claim 16, further comprising:
an optical filter having a first surface adhered within the first trench; and
a transparent member having a first surface adhered within the third trench such that the aperture is enclosed between the first surfaces of the optical filter and the transparent member.

18. The semiconductor apparatus of claim 17, further comprising:
an image sensor chip connected to a second surface of the transparent member; and
a mounting board electrically and physically connected to the image sensor chip.

19. The semiconductor apparatus of claim 18, wherein the transparent member, the image sensor chip and the mounting board are sequentially connected to each other and a body of the semiconductor apparatus by adhesive films to form one fixed body.

20. The semiconductor apparatus of claim 16, wherein a corner at which a bottom surface of the first trench meets the aperture or a corner at which a bottom surface of the third trench meets the aperture is beveled.

21. (canceled)
